(19) United States
(12) Patent Application Publication
(10) Pub. No.: US 2021/0373434 A1
(43) Pub. Date: Dec. 2, 2021

(54) TRANSPORT COMPLEX AND TRANSPORT MODULE INCLUDING THE SAME

(71) Applicant: Samsung Display Co., LTD., Yongin-si (KR)

(72) Inventors: SUKBIN JUNG, Hwaseong-si (KR); Sung Jin Na, Asan-si (KR)

(21) Appl. No.: 17/188,457

(22) Filed: Mar. 1, 2021

(30) Foreign Application Priority Data
May 26, 2020 (KR) 10-2020-0063189

(51) Int. Cl. G03F 1/40; G03F 1/48

(52) U.S. Cl. CPC G03F 1/40; G03F 1/48

(57) ABSTRACT

Transport complexes and transport modules including the same. The transport complex comprises a metal stick having one surface and other surface that are spaced apart from each other in one direction, a first protection sheet adjacent to the one surface, and a second protection sheet adjacent to the other surface. In wavelength ranges of about 380 nm to about 800 nm, each of the first and second protection sheets has transmittance of about 0% to about 50% and absorptance of less than about 95%.

### CROSS REFERENCE TO RELATED APPLICATION

This application claims priority from and the benefit of Korean Patent Application No. 10-2020-0063189, filed on May 26, 2020, which is hereby incorporated by reference for all purposes as if fully set forth herein.

### BACKGROUND

### Field

Exemplary embodiments of the inventive concept relate to a transport complex and a transport module including the same, and more particularly, to a transport complex including a protection sheet whose color and/or transparency are adjusted.

### Discussion of the Background

Photolithography is a process used in the formation of metal patterns on a substrate. The photolithography is employed in the fabrication of integrated circuits, of semiconductors including highly integrated circuits, and of display devices including semiconductors.

A metal stick may be used as a mask stick to form metal patterns, and a plurality of metal sticks may be delivered in a stacked state. A protection sheet may be provided between the stacked metal sticks during their delivery. The protection sheet requires a function to protect the metal stick while minimizing the occurrence of foreign substances.

The above information disclosed in this Background section is only for understanding of the background of the inventive concepts, and, therefore, it may contain information that does not constitute prior art.

### SUMMARY

Exemplary embodiments of the inventive concept provide a transport complex including a metal stick and a protection sheet that is easily separated from the metal stick and that avoids the occurrence of foreign substances.

Exemplary embodiments of the inventive concept also provide a transport module including a plurality of transport complexes each of which includes a metal stick and a protection sheet that is easily separated from the metal stick and that avoids the occurrence of foreign substances.

Additional features of the inventive concepts will be set forth in the description which follows, and in part will be apparent from the description, or may be learned by practice of the inventive concepts.

An exemplary embodiment of the inventive concept provides a transport complex including: a metal stick having a first surface and a second surface that are spaced apart from each other in one direction; a first protection sheet adjacent to the first surface; and a second protection sheet adjacent to the second surface. In wavelength ranges of about 380 nm to about 800 nm, each of the first and second protection sheets may have transmittance of about 0% to about 50% and absorptance of less than about 95%.

Each of the first and second protection sheets may include at least one selected from polypropylene, polystyrene, and polyethylene.

At least one selected from the first and second protection sheets may include a matte coating layer.

The first protection sheet may have a first surface and a second surface that are spaced apart from each other in the one direction. At least one selected from the first and second surfaces may be matt-coated.

Each of the first and second protection sheets may reflect light whose wavelength falls within a range between about 400 nm and about 800 nm, between about 570 nm and about 620 nm, or between about 380 nm and about 500 nm.

Each of the first and second protection sheets may include an antistatic agent.

Each of the first and second protection sheets may have a thickness of about 100 μm

The first protection sheet may entirely overlap the second protection sheet. Each of the first and second protection sheets may include an overlapping part that overlaps the metal stick and a non-overlapping part that does not overlap the metal stick. The non-overlapping part may be disposed outside the overlapping part.

The metal stick may be a mask stick used in photolithography. When viewed in plan, each of the first and second protection sheets may have an area greater than an area of the mask stick.

When viewed in plan, each of the first protection sheet, the second protection sheet, and the metal stick may have a tetragonal shape including two long sides and two short sides. The long side of each of the first and second protection sheets may have a length that is at least 20 mm greater than a length of the long side of the metal stick. The short side of each of the first and second protection sheets may have a length that is at least 10 mm greater than a length of the short side of the metal stick.

The metal stick may be an alloy of nickel and iron.

Another exemplary embodiment of the inventive concept provides a transport module including: a plurality of metal sticks that are stacked in one direction; and at least two protection sheets between the metal sticks. In wavelength ranges of about 380 nm to about 800 nm, each of the protection sheets may have transmittance of about 0% to about 50% and absorptance of less than about 95%.

The plurality of metal sticks and the at least two protection sheets may constitute a first transport complex and a second transport complex that neighbor each other. Each of the first and second transport complexes may include: one of the plurality of metal sticks; and a first protection sheet and a second protection sheet that are correspondingly adjacent to a top surface and a bottom surface of the metal stick.

Each of the protection sheets may include at least one selected from polypropylene, polystyrene, and polyethylene.

Each of the protection sheets may have a first surface and a second surface that are spaced apart from each other in the one direction. At least one selected from the first and second surfaces may be matt-coated.

The first surface may be matt-coated. The first surface may be disposed at an upper side in the one direction.

Each of the protection sheets may reflect light whose wavelength falls within a range between about 400 nm and about 800 nm, between about 570 nm and about 620 nm, or between about 380 nm and about 500 nm.

Each of the protection sheets may include an antistatic agent.

An average number of foreign substances on one surface of each of the metal sticks may be about 20 or less. The surfaces of the metal sticks may be in contact with the protection sheets.

The metal sticks may include a first metal stick and a second metal stick that are sequentially stacked. The protection sheets may be disposed on the first metal stick, between the first metal stick and the second metal stick, and below the second metal stick.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the inventive concepts.

FIG. 1 illustrates an exploded perspective view showing a transport complex according to exemplary embodiments.

FIG. 2 illustrates an exploded perspective view showing a transport complex according to exemplary embodiments.

FIG. 3 illustrates a cross-sectional view taken along line I-I′ of FIG. 1.

FIG. 4 illustrates a cross-sectional view showing a transport complex according to exemplary embodiments.

FIG. 5 illustrates an exploded perspective view showing a transport module according to exemplary embodiments.

FIG. 6 illustrates a graph showing the number of foreign substances included in metal sticks.

### DETAILED DESCRIPTION

In the following description, for the purposes of explanation, numerous specific details are set forth in order to provide a thorough understanding of various exemplary embodiments of the invention. As used herein “embodiments” are non-limiting examples of devices or methods employing one or more of the inventive concepts disclosed herein. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an exemplary embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

The following will now discuss a transport complex and a transport module including the same according to exemplary embodiments of the inventive concept with reference to the accompanying drawings.

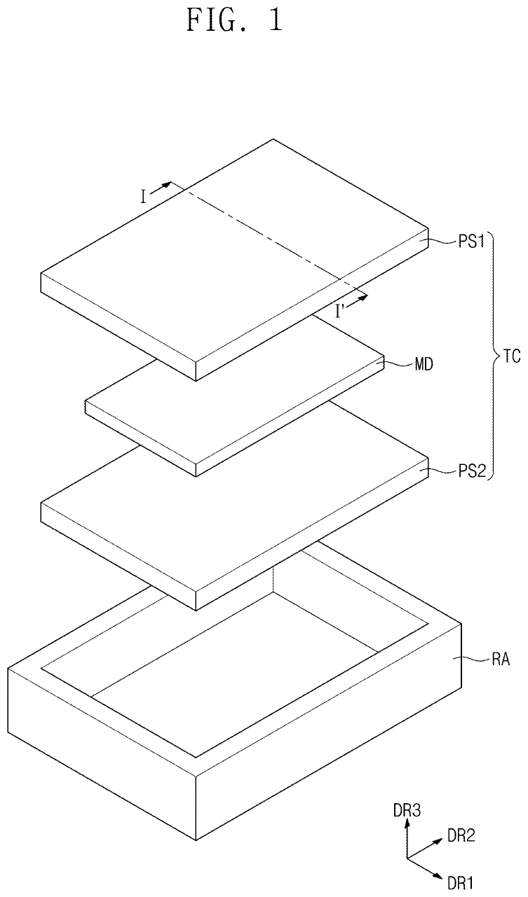

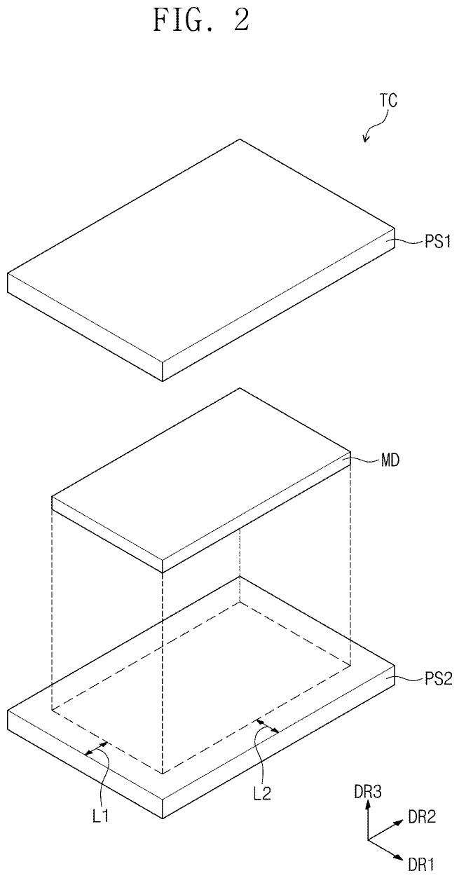

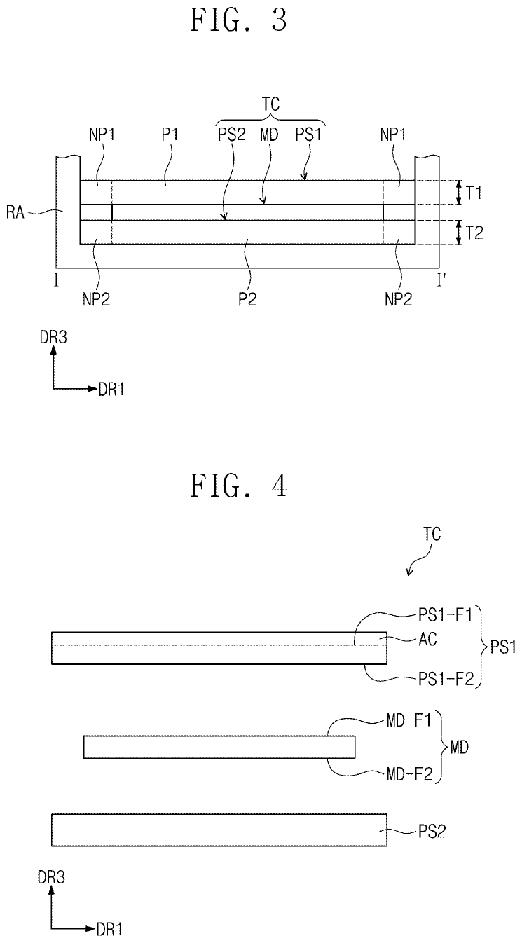

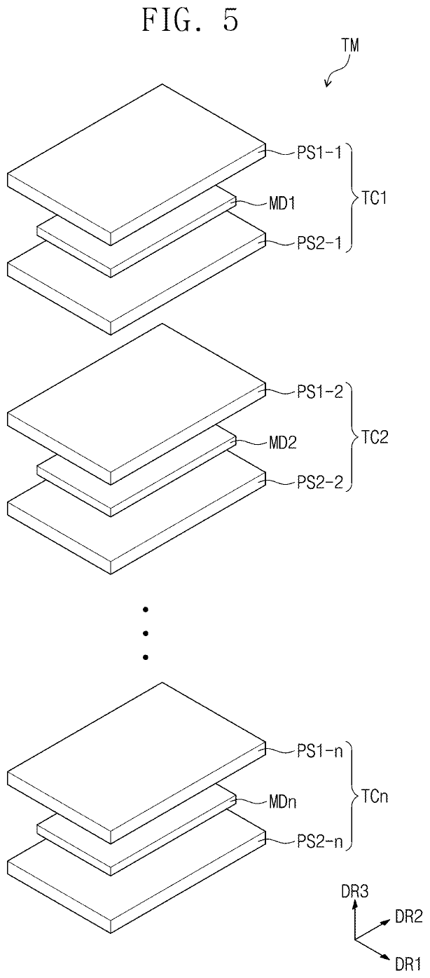

FIG. 1 illustrates an exploded perspective view showing a transport complex TC according to exemplary embodiments. FIG. 2 illustrates an exploded perspective view showing the transport complex TC according to exemplary embodiments. FIG. 3 illustrate a cross-sectional view taken along line I-I′ of FIG. 1, showing the transport complex TC accommodated in a tray RA. FIG. 4 illustrates a cross-sectional view showing the transport complex TC according to exemplary embodiments. FIG. 5 illustrates an exploded perspective view showing a transport module TM according to exemplary embodiments.

Referring to FIG. 1, the tray RA may deliver the transport complex TC according to some exemplary embodiments. The tray RA may accommodate the transport complex TC. The tray RA may be a tool to deliver the transport complex TC. This, however, is merely exemplary, and other types of apparatuses or tools may be used to deliver the transport complex TC. FIG. 1 shows a single transport complex TC, but a plurality of transport complexes may be accommodated in the tray RA. For example, the tray RA may receive twenty transport complexes TC therein. The twenty transport complexes TC may be delivered in a stacked state.

The transport complex TC according to exemplary embodiments may include a metal stick MD and protection sheets PS1 and PS2. The protection sheets PS1 and PS2 may include a first protection sheet PS1 and a second protection sheet PS2, and may optionally further include at least one protection sheet. The transport module TM according to exemplary embodiments may include a plurality of metal sticks and at least two protection sheets disposed between the metal sticks. The transport module TM will be further discussed below in detail with reference to FIG. 5.

The metal stick MD may have a first surface MD-F1 and a second surface MD-F2 that are spaced apart from each other in one direction (see FIG. 4). The first surface MD-F1 and the second surface MD-F2 may be spaced apart from each other in a direction along which a third directional axis DR3 extends. The first surface MD-F1 and the second surface MD-F2 of the metal stick MD may respectively be a top surface (or front surface) and a bottom surface (or rear surface) of the metal stick MD.

The protection sheets PS1 and PS2 may be disposed adjacent to the first surface MD-F1 and the second surface MD-F2 of the metal stick MD. The first protection sheet PS1 and the second protection sheet PS2 may be respectively adjacent to the first surface MD-F1 and the second surface MD-F2 of the metal stick MD. For example, the first protection sheet PS1 may be disposed close to the first surface MD-F1, or the top surface, of the metal stick MD. The second protection sheet PS2 may be disposed close to the second surface MD-F2, or the bottom surface, of the metal stick MD. As the protection sheets PS1 and PS2 are each disposed adjacent to the metal stick MD, the protection sheets PS1 and PS2 may protect the metal stick MD during its delivery.

The transport complex TC may be configured such that the metal stick MD is provided between the first protection sheet PS1 and the second protection sheet PS2 that face each other. The metal stick MD may be provided below the first protection sheet PS1, and the second protection sheet PS2 may be provided below the metal stick MD. The first protection sheet PS1, the metal stick MD, and the second protection sheet PS2 may be sequentially stacked to constitute the transport complex TC.

The first and second protection sheets PS1 and PS2 may be opaque. According to exemplary embodiments, each of the first and second protection sheets PS1 and PS2 may have transmittance of about 0% to about 50% in wavelength ranges of about 380 nm to about 800 nm. In wavelength ranges of about 380 nm to about 800 nm, opacity may increase as the transmittance approaches 0%.

Each of the first and second protection sheets PS1 and PS2 may have absorptance of less than about 95% in wavelength ranges of about 380 nm to about 800 nm. In wavelength ranges of about 380 nm to about 800 nm, an object whose absorptance is greater than about 95% may be visible as black. When the first and second protection sheets PS1 and PS2 have their absorptance of less than about 95% in wavelength ranges of about 380 nm to about 800 nm, each of the first and second protection sheets PS1 and PS2 may not be black. Each of the first and second protection sheets PS1 and PS2 may have a color other than black. For example, each of the first and second protection sheets PS1 and PS2 may have a white color. For another example, each of the first and second protection sheets PS1 and PS2 may have a yellow color. Alternatively, the first and second protection sheets PS1 and PS2 may have different colors from each other. The first protection sheet PS1 may have a white color, and the second protection sheet PS2 may have a yellow color. This, however, is merely exemplary, and no limitation is imposed on the color of the first and second protection sheets PS1 and PS2.

For example, in wavelength ranges of about 380 nm to about 800 nm, the first protection sheet PS1 may have transmittance of about 0% and absorptance of less than about 95%. In wavelength ranges of about 380 nm to about 800 nm, the second protection sheet PS2 may have transmittance of about 0% and absorptance of less than about 95%.

According to exemplary embodiments, each of the first and second protection sheets PS1 and PS2 may reflect light whose wavelength falls within a range between about 400 nm and about 800 nm, between about 570 nm and about 620 nm, or between about 425 nm and about 495 nm. For example, each of the first and second protection sheets PS1 and PS2 may reflect light having a wavelength of about 400 nm to about 800 nm. An object that mostly reflects light having a wavelength of about 400 nm to about 800 nm may be visible as white. Alternatively, each of the first and second protection sheets PS1 and PS2 may reflect light having a wavelength of about 570 nm to about 620 nm. Dissimilarly, each of the first and second protection sheets PS1 and PS2 may reflect light having a wavelength of about 425 nm to about 495 nm.

For example, in wavelength ranges of about 300 nm to about 800 nm, when the first protection sheet PS1 has transmittance of about 0% and mostly reflects light having a wavelength of about 400 nm to about 800 nm, the first protection sheet PS1 may have an opaque white color. In wavelength ranges of about 300 nm to about 800 nm, when the first protection sheet PS1 has transmittance of about 0% and reflects light having a wavelength of about 590 nm to about 620 nm, the first protection sheet PS1 may have an opaque orange color. In wavelength ranges of about 300 nm to about 800 nm, when the first protection sheet PS1 has transmittance of about 0% and reflects light having a wavelength of about 570 nm to about 590 nm, the first protection sheet PS1 may have an opaque yellow color. In wavelength ranges of about 300 nm to about 800 nm, when the first protection sheet PS1 has transmittance of about 0% and reflects light having a wavelength of about 450 nm to about 500 nm, the first protection sheet PS1 may have an opaque blue color. In wavelength ranges of about 300 nm to about 800 nm, when the first protection sheet PS1 has transmittance of about 0% and reflects light having a wavelength of about 420 nm to about 450 nm, the first protection sheet PS1 may have an opaque indigo color. This, however, is merely exemplary, and the inventive concept is not limited to the mentioned above.

When each of the first and second protection sheets PS1 and PS2 has transmittance of about 0% to about 50% in wavelength ranges of about 380 nm to about 800 nm, the metal stick MD and the protection sheets PS1 and PS2 may be easily separated from each other. The protection sheets PS1 and PS2 may be provided to protect the metal stick MD during its delivery. After the delivery of the metal stick MD, an adsorption apparatus may be employed to separate the protection sheets PS1 and PS2 from the metal stick MD. The adsorption apparatus may use a camera to recognize the metal stick MD and the protection sheets PS1 and PS2, and may separate each of the protection sheets PS1 and PS2 from the metal stick MD. When the protection sheets PS1 and PS2 have their transmittance of greater than about 50%, the camera of the adsorption apparatus may not recognize the protection sheets PS1 and PS2 that are disposed adjacent to the metal stick MD. When the camera of the adsorption apparatus does not recognize the protection sheets PS1 and PS2, the protection sheets PS1 and PS2 may not be separated from the metal stick MD, but may be left in a state of being close to the metal stick MD.

The protection sheets PS1 and PS2 included in the transport complex TC according to exemplary embodiments may have their transmittance of about 0% to about 50% in wavelength ranges of about 380 nm to about 800 nm, and the camera of the adsorption apparatus may have an increased recognition rate for the protection sheets PS1 and PS2. In addition, the protection sheets PS1 and PS2 according to exemplary embodiments may have their absorptance of less than about 95% in wavelength ranges of about 380 nm to about 800 nm, and may have their colors other than black. The camera of the adsorption apparatus may readily recognize the protection sheets PS1 and PS2 having colors other than black. Therefore, the protection sheets PS1 and PS2 may be easily separated from the metal stick MD.

Each of the first and second protection sheets PS1 and PS2 may include at least one selected from polypropylene, polystyrene, and polyethylene. For example, each of the first and second protection sheets PS1 and PS2 may include polypropylene. When a protection sheet including cellulose is used to deliver a metal stick, many foreign substances may be generated from cellulose of the protection sheet. Cellulose may not be included in each of the protection sheets PS1 and PS2 according to exemplary embodiments of the inventive concept, and accordingly, fewer foreign substances may be produced from the protection sheets PS1 and PS2.

An antistatic agent may be included in each of the first and second protection sheets PS1 and PS2 according to exemplary embodiments. Each of the protection sheets PS1 and PS2 may include conductive carbon, conductive polymer, nano-metal, or surfactant as the antistatic agent, but the material of the antistatic agent is not particularly limited. The conductive carbon may be, for example, carbon black. The conductive polymer may be, for example, polyaniline, polypyrrole, or polythiophene. The nano-metal may be, for example, indium thin oxide (ITO), antimony-doped thin oxide (ATO), or silver (Ag). The surfactant may be, for example, an amine-based surfactant, a glycerin-based surfactant, ammonium salt, sulfonate, phosphate, phosphoric acid, or a betaine-based compound. When the protection sheets PS1 and PS2 include the antistatic agent, it may be possible to discharge static electricity occurring at the metal stick MD. Accordingly, when the metal stick MD, the first protection sheet PS1, and the second protection sheet PS2 are separated from each other, the protection sheets PS1 and PS2 may be prevented from being attached to the metal stick MD.

When viewed in plan, the first protection sheet PS1, the second protection sheet PS2, and the metal stick MD may each have a tetragonal shape including two long sides and two short sides. The metal stick MD may be a mask stick shaped like a tetragon, including two long sides and two short sides. This, however, is merely exemplary, and no limitation is imposed on the shape of the first protection sheet PS1, of the second protection sheet PS2, and of the metal stick MD. The metal stick MD may be an alloy including nickel (Ni) and iron (Fe). For example, the metal stick MD may be made of stainless steel, including nickel and iron.

FIG. 2 depicts that the first protection sheet PS1, the second protection sheet PS2, and the metal stick MD have their long sides parallel to a direction along which a second directional axis DR2 extends. FIG. 2 also depicts that the first protection sheet PS1, the second protection sheet PS2, and the metal stick MD have their short sides parallel to a direction along which a first directional axis DR1 extends.

According to exemplary embodiments, when viewed in plan, each of the first and second protection sheets PS1 and PS2 may have an area greater than that of the metal stick MD. The first and second protection sheets PS1 and PS2 may have their long sides each of which has a length greater than that of each long side of the metal stick MD. The first and second protection sheets PS1 and PS2 may have their short sides each of which has a length greater than that of each short side of the metal stick MD. The length of each long side of the first protection sheet PS1 may be greater than that of each long side of the metal stick MD. The length of each short side of the first protection sheet PS1 may be greater than that of each short side of the metal stick MD. The length of each long side of the second protection sheet PS2 may be greater than that of each long side of the metal stick MD. The length of each short side of the second protection sheet PS2 may be greater than that of each short side of the metal stick MD.

Referring to FIG. 2, the length of the long side of the second protection sheet PS2 may be at least L1 greater than that of the long side of the metal stick MD. The L1 may be a difference in length between the long side of the second protection sheet PS2 and the long side of the metal stick MD, The L1 may correspond to a minimum distance from one point on the short side of the metal stick MD to one point on the short side of the second protection sheet PS2, and may be parallel to a direction along which the second directional axis DR2 extends. The L1 may be equal to or greater than about 10 mm. The length of the long side of the second protection sheet PS2 may be increased by equal to or greater than about 10 mm from each of opposite ends of the long side of the metal stick MD. In such cases, the length of the long side of the second protection sheet PS2 may be at least about 20 mm greater than that of the long side of the metal stick MD.

In addition, the length of the short side of the second protection sheet PS2 may be at least L2 greater than that of the short side of the metal stick MD. The L2 may be a difference in length between the short side of the second protection sheet PS2 and the short side of the metal stick MD, The L2 may correspond to a minimum distance from one point on the long side of the metal stick MD to one point on the long side of the second protection sheet PS2, and may be parallel to a direction along which the first directional axis DR1 extends. The L2 may be equal to or greater than about 5 mm. The length of the short side of the second protection sheet PS2 may be increased by equal to or greater than about 5 mm from each of opposite ends of the short side of the metal stick MD. In such cases, the length of the short side of the second protection sheet PS2 may be at least about 10mm greater than that of the short side of the metal stick MD.

Referring to FIG. 3, the first protection sheet PS1 may entirely overlap the second protection sheet PS2. The first and second protection sheets PS1 and PS2 may include their overlapping parts P1 and P2 that overlap the metal stick MD, and may also include their non-overlapping parts NP1 and NP2 that do not overlap the metal stick MD. For the first and second protection sheets PS1 and PS2, the non-overlapping parts NP1 and NP2 may be disposed outside corresponding overlapping parts P1 and P2. The first protection sheet PS1 may include a first overlapping part P1 that overlaps the metal stick MD and a first non-overlapping part NP1 that does not overlap the metal stick MD. The first non-overlapping part NP1 may be disposed outside the first overlapping part P1. The second protection sheet PS2 may include a second overlapping part P2 that overlaps the metal stick MD and a second non-overlapping part NP2 that does not overlap the metal stick MD. The second non-overlapping part NP2 may be disposed outside the second overlapping part P2. When viewed in plan, the first overlapping part P1 of the first protection sheet PS1 may be in contact with the second overlapping part P2 of the second protection sheet PS2.

As discussed above, each of the first and second protection sheets PS1 and PS2 may have an area greater than that of the metal stick MD, and accordingly, the long and short sides of the first protection sheet PS1 may be respectively adjacent to the long and short sides of the second protection sheet PS2. The long side of the first protection sheet PS1 may be in contact with the long side of the second protection sheet PS2. The short side of the first protection sheet PS1 may be in contact with the short side of the second protection sheet PS2.

The first and second protection sheets PS1 and PS2 may have their thicknesses T1 and T2 each of which ranges from about 100 μm to about 500 μm. When viewed in a direction along which the third directional axis DR3 extends, the thickness T1 of the first protection sheet PS1 may range from about 100 μm to about 500 μm. When viewed in a direction along which the third directional axis DR3 extends, the thickness T2 of the second protection sheet PS2 may range from about 100 μm to about 500 μm.

In the transport complex TC according to exemplary embodiments, one or both of the first and second protection sheets PS1 and PS2 may include a matte coating layer. Each of the first and second protection sheets PS1 and PS2 may have a first surface and a second surface that are spaced apart from each other in a direction along which the third directional axis DR3 extends. The first protection sheet PS1 may have a first surface PS1-F1 and a second surface PS1-F2 at least one of which is matt-coated. The second protection sheet PS2 may have a first surface and a second surface, at least one of which is matt-coated. For example, of the first and second protection sheets PS1 and PS2, only the first protection sheet PS1 may include a matte coating layer AC, and the first surface PS1-F1 of the first protection sheet PS1 may be matt-coated. Alternatively, the first and second protection sheets PS1 and PS2 may all include a matte coating layer AC, and the first surface PS1-F1 of the first protection sheet PS1 and the first surface of the second protection sheet PS2 may all be matt-coated. This, however, is merely exemplary, and the inventive concept is not limited to the mentioned above.

FIG. 4 depicts that the first protection sheet PS1 includes the matte coating layer AC. The inventive concept, however, is not limited thereto, and each of the first and second protection sheets PS1 and PS2 may include the matte coating layer AC.

The first protection sheet PS1 is illustrated such that, when viewed in a direction along which the third directional axis DR3 extends, the matt-coated first surface PS1-F1 is disposed at an upper side and the second surface PS1-F2 is disposed at a lower side. The inventive concept, however, is not limited thereto, and the first and second surfaces PS1-F1 and PS1-F2 of the first protection sheet PS1 may all be matt-coated. The matte coating layer AC may be recognized by the camera of the adsorption apparatus discussed above. The camera of the adsorption apparatus may recognize a matt-coated surface among the first and second surfaces of the first and second protection sheets PS1 and PS2. A protection sheet including a matte coating layer may be recognized at an increased rate by the camera of the adsorption apparatus, and thus, a metal stick and the protection sheet may be easily separated from each other.

The transport complex TC according to exemplary embodiments may include a metal stick MD having one surface MD-F1 and other surface MD-F2 that are spaced apart from each other, a first protection sheet PS1 adjacent to the one surface MD-F1 of the metal stick MD, and a second protection sheet PS2 adjacent to the other surface MD-F2 of the metal stick MD. The protection sheets PS1 and PS2 may be provided for delivery of the metal stick MD. Each of the protection sheets PS1 and PS2 may have transmittance of about 0% to about 50% in wavelength ranges of about 380 nm to about 800 nm. Each of the protection sheets PS1 and PS2 may have absorptance of less than about 95% in wavelength ranges of about 380 nm to about 800 nm. Accordingly, the camera of the adsorption apparatus may have an increased recognition rate for the protection sheets PS1 and PS2 included in the transport complex TC according to exemplary embodiments, and the metal stick MD and the protection sheets PS1 and PS2 may be easily separated from each other. In addition, the protection sheets PS1 and PS2 according to exemplary embodiments may include polypropylene and may exhibit a reduced occurrence of foreign substances.

With reference to FIG. 5, the transport module TM will be described according to exemplary embodiments. Repetitive descriptions of the same components as those discussed with reference to FIGS. 1 to 4 will be omitted.

The transport module TM may include a plurality of metal sticks MD1, MD2, . . . , and MDn, and a plurality of protection sheets PS1-1, PS2-1, PS1-2, PS2-2, . . . , PS1-n, and PS2-n disposed between the metal sticks MD1, MD2, . . . , and MDn. The protection sheets PS1-1, PS2-1, PS1-2, PS2-2, . . . , PS1-n, and PS2-n may be one of the first and second protection sheets PSI and PS2 discussed above.

The transport module TM may include a plurality of transport complexes TC1, TC2, . . . , and TCn. The plurality of transport complexes TC1, TC2, . . . , and TCn may include a first transport complex TC1 and a second transport complex TC2 that neighbor each other. The first transport complex TC1 may include a first metal stick MD1, a first protection sheet PS1-1, and a second protection sheet PS2-1. The second transport complex TC2 may include a second metal stick MD2, an another first protection sheet PS1-2, and an another second protection sheet PS2-2. The first protection sheet PS1-1 and the another first protection sheet PS1-2 may be the same as the first protection sheet PS1 discussed in FIGS. 1 to 4. The second protection sheet PS2-1 and the another second protection sheet PS2-2 may be the same as the second protection sheet PS2 discussed in FIGS. 1 to 4. Although not shown, the transport module TM may be accommodated in the tray RA discussed above.

The protection sheets PS1-1, PS2-1, PS1-2, and PS2-2 may be disposed on the first metal stick MD1, between the first metal stick MD1 and the second metal stick MD2, and below the second metal stick MD2. The first protection sheet PS1-1 may be disposed on the first metal stick MD1, and the another second protection sheet PS2-2 may be disposed below the second metal stick MD2. In addition, the another first protection sheet PS1-2 and the second protection sheet PS2-1 may be disposed between the first metal stick MD1 and the second metal stick MD2.

Two protection sheets PS1-2 and PS2-1 may be disposed between the first metal stick MD1 and the second metal stick MD2. The first metal stick MD1 may be included in the first transport complex TC1. The second metal stick MD2 may be included in the second transport complex TC2. The protection sheets PS1-1, PS2-1, PS2-1, and PS2-2 included in the transport complexes TC1 and TC2 may be disposed adjacent to each other. The second protection sheet PS2-1 included in the first transport complex TC1 may be disposed adjacent to the another first protection sheet PS1-2 included in the second transport complex TC2.

According to exemplary embodiments, one or both of the first protection sheet PS1-1 and the second protection sheet PS2-1 may include a matte coating layer. One or both of the another first protection sheet PS1-2 and the another second protection sheet PS2-2 may include a matte coating layer. A matte coating layer may be included in each of the first protection sheet PS1-1 and the another first protection sheet PS1-2 each of which is disposed at an upper side in a direction along which the third directional axis DR3 extends. For example, a matte coating layer may be included in one or both of two protection sheets that belong to each of the transport complexes TC1, TC2, . . . , and TCn.

According to exemplary embodiments, each of the protection sheets PS1-1, PS2-1, PS1-2, PS2-2, . . . , PS1-n, and PS2-n may have transmittance of about 0% to about 50% in wavelength ranges of about 380 nm to about 800 nm. Each of the protection sheets PS1-1, PS2-1, PS1-2, PS2-2, . . . , PS1-n, and PS2-n may have absorptance of about 0% to about 50% in wavelength ranges of about 380 nm to about 800 nm. Each of the protection sheets PS1-1, PS2-1, PS1-2, PS2-2, . . . , PS1-n, and PS2-n may have a color other than black.

Each of the protection sheets PS1-1, PS2-1, PS1-2, PS2-2, . . . , PS1-n, and PS2-n may include at least one selected from polypropylene, polystyrene, and polyethylene. For example, each of the protection sheets PS1-1, PS2-1, PS1-2, PS2-2, . . . , PS1-n, and PS2-n may include polypropylene.

An average number of foreign substances present on one surface of each of the metal sticks MD1, MD2, . . . , and MDn may be less than 20. The one surface of each of the metal sticks MD1, MD2, . . . , and MDn may be in contact with a corresponding one of the protection sheets PS1-1, PS2-1, PS1-2, PS2-2, . . . , PS1-n, and PS2-n. On the one surface of each of the metal sticks MD1 to MDn, there may be observed foreign substances whose average number is about 20 or less. For example, about ten or fewer foreign substances may be observed on the one surface of each of the metal sticks MD1 to MDn.

In addition, each of the protection sheets PS1-1, PS2-1, PS1-2, PS2-2, . . . , PS1-n, and PS2-n may include an antistatic agent. None of the protections sheets PS1-1, PS2-1, PS1-2, PS2-2, . . . , PS1-n, and PS2-n including the antistatic agent may be attached to the metal sticks MD1, MD2, . . . , and MDn.

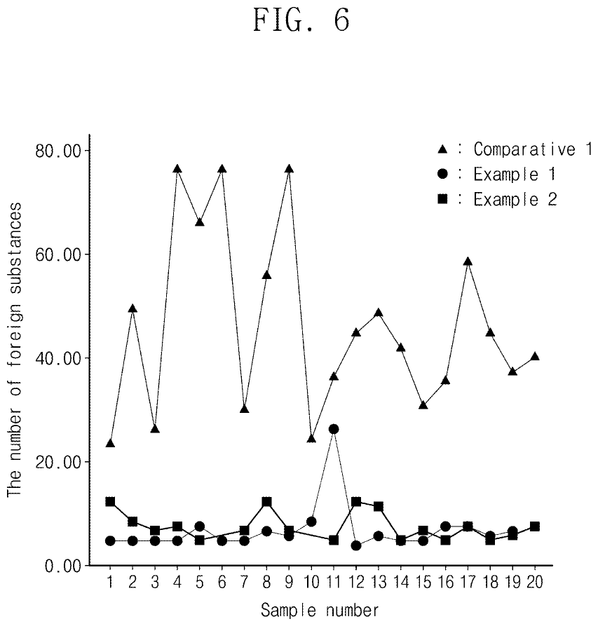

FIG. 6 is a graph showing the number of foreign substances observed on a surface of each of metal sticks included in a transport module. A transport module includes twenty transport complexes that are sequentially stacked, and the graph of FIG. 6 shows the number of foreign substances measured on each of twenty metal sticks. Comparative 1 relates to metal sticks on which are stacked protection sheets including cellulose, and each of Examples 1 and 2 relates to metal sticks on which are stacked protection sheets according to exemplary embodiments. The metal sticks of Example 1 are stacked thereon with protection sheets that reflect light having a wavelength of about 380 nm to about 450 nm. The metal sticks of Example 2 are stacked thereon with protection sheets that reflect light having a wavelength of about 400 nm to about 800 nm. For example, the metal sticks of Example 1 are stacked thereon with purple-colored protection sheets, and the metal sticks of Example 2 are stacked thereon with white-colored protection sheets. A measurement result for the metal sticks on which white-colored protection sheets are stacked according to Example 2 may be analogous to that for metal sticks on which yellow-colored protection sheets are stacked. A protection sheet that reflects light having a wavelength of about 570 nm to about 590 nm may be visible yellow.

Referring to the graph of FIG. 6, it may be found that each of the metal sticks in Comparative 1 has, on a surface thereof, 20 or more foreign substances and a maximum number of foreign substances approaches about 80. In contrast, it may be found that each of the metal sticks in Examples 1 and 2 has, on a surface thereof, foreign substances whose number is mostly less than about 20.

An average number of foreign substances observed on the surface of each of the metal sticks in Comparative 1 is about 45, and an average number of foreign substances observed on the surface of each of the metal sticks in Examples 1 and 2 is about 3.5. Accordingly, it may be ascertained that each of the metal sticks delivered by using the protection sheet according to exemplary embodiments has a reduced number of foreign substances present on the surface thereof.

A transport complex may include a metal stick, a first protection sheet disposed adjacent to the metal stick, and a second protection sheet disposed adjacent to the metal stick. In wavelength ranges of about 380 nm to about 800 nm, each of the first and second protection sheets may have transmittance of about 0% to about 50% and absorptance of less than about 95%. Therefore, each of the first and second protection sheets according to exemplary embodiments may be easily separated from the metal stick. In addition, neither the first nor the second protection sheet may include cellulose, and the protection sheets may be reduced or prevented from producing foreign substances.

A transport module according to exemplary embodiments may include a plurality of transport complexes, and may have characteristics to easily separate the protection sheets from the metal sticks and to avoid the occurrence of foreign substances from the protection sheets.

A transport complex according to exemplary embodiments may provide a metal stick and a protection sheet that is easily separated from the metal stick and that avoids the occurrence of foreign substances.

Moreover, there may be provided a transport module including a plurality of transport complexes each of which includes a metal stick and a protection sheet that is easily separated from the metal stick and that avoids the occurrence of foreign substances.

Although certain exemplary embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A transport complex, comprising:
a metal stick having a first surface and a second surface that are spaced apart from each other in one direction;
a first protection sheet adjacent to the first surface; and
a second protection sheet adjacent to the second surface,
wherein, in wavelength ranges of about 380 nm to about 800 nm, each of the first and second protection sheets has transmittance of about 0% to about 50% and absorptance of less than about 95%.

2. The transport complex of claim 1, wherein each of the first and second protection sheets includes at least one selected from polypropylene, polystyrene, and polyethylene.

3. The transport complex of claim 1, wherein at least one selected from the first and second protection sheets includes a matte coating layer.

4. The transport complex of claim 1, wherein:
the first protection sheet has a first surface and a second surface that are spaced apart from each other in the one direction; and
at least one selected from the first and second surfaces is matt-coated.

5. The transport complex of claim 1, wherein each of the first and second protection sheets reflects light whose wavelength falls within a range between about 400 nm and about 800 nm, between about 570 nm and about 620 nm, or between about 380 nm and about 500 nm.

6. The transport complex of claim 1, wherein each of the first and second protection sheets includes an antistatic agent.

7. The transport complex of claim 1, wherein each of the first and second protection sheets has a thickness of about 100 μm to about 500 μm.

8. The transport complex of claim 1, wherein:
the first protection sheet entirely overlaps the second protection sheet; and
each of the first and second protection sheets includes an overlapping part that overlaps the metal stick and a non-overlapping part that does not overlap the metal stick, the non-overlapping part being disposed outside the overlapping part.

9. The transport complex of claim 1, wherein:
the metal stick is a mask stick used in photolithography; and
when viewed in plan, each of the first and second protection sheets has an area greater than an area of the mask stick.

10. The transport complex of claim 1, wherein:
when viewed in plan, each of the first protection sheet, the second protection sheet, and the metal stick has a tetragonal shape including two long sides and two short sides;
the long side of each of the first and second protection sheets has a length that is at least 20 mm greater than a length of the long side of the metal stick; and
the short side of each of the first and second protection sheets has a length that is at least 10 mm greater than a length of the short side of the metal stick.

11. The transport complex of claim 1, wherein the metal stick comprises an alloy of nickel and iron.

12. A transport module, comprising:
a plurality of metal sticks that are stacked in one direction; and
at least two protection sheets between the metal sticks,
wherein, in wavelength ranges of about 380 nm to about 800 nm, each of the protection sheets has transmittance of about 0% to about 50% and absorptance of less than about 95%.

13. The transport module of claim 12, wherein:
the plurality of metal sticks and the at least two protection sheets constitute a first transport complex and a second transport complex that neighbor each other; and
each of the first and second transport complexes includes:
one of the plurality of metal sticks; and
a first protection sheet and a second protection sheet that are correspondingly adjacent to a top surface and a bottom surface of the metal stick.

14. The transport module of claim 12, wherein each of the protection sheets includes at least one selected from polypropylene, polystyrene, and polyethylene.

15. The transport module of claim 12, wherein:
each of the protection sheets has a first surface and a second surface that are spaced apart from each other in the one direction; and
at least one selected from the first and second surfaces is matt-coated.

16. The transport module of claim 15, wherein:
the first surface is matt-coated; and
the first surface is disposed at an upper side in the one direction.

17. The transport module of claim 12, wherein each of the protection sheets reflects light having a wavelength in a range between about 400 nm and about 800 nm, between about 570 nm and about 620 nm, or between about 380 nm and about 500 nm.

18. The transport module of claim 12, wherein each of the protection sheets includes an antistatic agent.

19. The transport module of claim 12, wherein an average number of foreign substances on one surface of each of the metal sticks is about 20 or less, the surfaces of the metal sticks being in contact with the protection sheets.

20. The transport module of claim 12, wherein:
the metal sticks include a first metal stick and a second metal stick that are sequentially stacked; and
the protection sheets are disposed on the first metal stick, between the first metal stick and the second metal stick, and below the second metal stick.
